(19) United States
(12) Patent Application Publication
(10) Pub. No.: US 2023/0036544 A1
(43) Pub. Date: Feb. 2, 2023

(54) DUAL-MODE IMAGE SENSOR AND COLOR FILTER ARRAY THEREOF

(71) Applicant: Himax Imaging Limited, Tainan City (TW)

(72) Inventor: Tsung Hsun Tsai, Tainan City (TW)

(21) Appl. No.: 17/391,595

(22) Filed: Aug. 2, 2021

(51) Int. Cl. H01L 27/146; G02B 5/20; H04N 9/04; H04N 5/33; G06K 9/20

(52) U.S. Cl. CPC H01L 27/14621; G02B 5/201; G02B 5/208; H04N 9/0451; H04N 5/332; G06K 9/209

(57) ABSTRACT

A color filter array includes a plurality of pixel filters arranged in a predetermined pattern composed of 2×2 pixel filters including two infrared filters and two visible filters. The two infrared filters in the predetermined pattern are disposed along one diagonal, and the two visible filters in the predetermined pattern are disposed along another diagonal.

### BACKGROUND OF THE INVENTION

### 1. Field of the Invention

The present invention generally relates to a color filter array, and more particularly to a color filter array with infrared filters.

### 2. Description of Related Art

A color filter array (CFA) is composed of tiny color filters placed over the pixel sensors of an image sensor, and is used to capture color information for digital imaging.

A Bayer filter is one type of CFA for arranging RGB color filters on a square grid of photo sensors. The Bayer filter is widely adapted to image sensors in digital cameras. The pattern of Bayer filter is half green, one quarter red and one quarter blue. That is, within the square grid of four photo sensors, there are two green filters, one red filter and one blue filter.

A modified Bayer filter has been proposed by replacing one green filter with an infrared (IR) filter. Therefore, constituent filters are one quarter green, one quarter red, one quarter blue and one quarter infrared. That is, within the square grid of four photo sensors, there are one green filter, one red filter, one blue filter and one infrared filter.

Another modified Bayer filter has been proposed with constituent filters that are half green, one eighth red, one eighth blue and one quarter infrared. Therefore, within the square grid of four photo sensors, there are two green filters, one red or blue filter, and one infrared filter.

For the conventional modified Bayer filters as mentioned above, an infrared image is obtained by subsampling. That is, the signal corresponding to the IR filter in each 2×2 pixels pattern is read out as the IR signal. It is noted that this read out method suffers limited sensitivity and signal-to-noise ratio. Moreover, a color image obtained from the conventional modified Bayer filters possesses substantive artifact.

A need has thus arisen to propose a novel color filter array with infrared filters to overcome drawbacks of the conventional modified Bayer filters.

### SUMMARY OF THE INVENTION

In view of the foregoing, it is an object of the embodiment of the present invention to provide a color filter array (CFA) adaptable to an image sensor with higher sensitivity and less artifact, and applicable to artificial intelligence applications. It is another object of the embodiment of the present invention to provide a dual-mode image sensor capable of simultaneously and separately providing infrared image and monochrome/color image, thereby providing cost effective solution and allowing flexibility on video camera.

According to one embodiment, a dual-mode image sensor includes a plurality of pixel sensors and a plurality of pixel filters. The pixel filters are correspondingly aligned with the plurality of pixel sensors, and the pixel filters are arranged in a predetermined pattern composed of 2×2 pixel filters including two infrared filters and two visible filters. Infrared signals from pixel sensors corresponding to the infrared filters and visible signals from pixel sensors corresponding to the white filters are read out separately.

### BRIEF DESCRIPTION OF THE DRAWINGS

FIG. 1A shows a perspective view of a color filter array (CFA) disposed on an image sensor according to a first embodiment of the present invention;

FIG. 1B shows a top view of the CFA of FIG. 1A;

FIG. 1C shows a schematic curve of transmission versus wavelength of a lens with dual band filtering adaptable to the CFA of FIG. 1A;

FIG. 2 schematically shows a method of reading out signals from the image sensor of FIG. 1A;

FIG. 3A shows a perspective view of a color filter array (CFA) disposed on an image sensor according to a second embodiment of the present invention;

FIG. 3B shows a top view of the CFA of FIG. 3A;

FIG. 3C shows schematic curves of transmission versus wavelength of a red filter, a green filter and a blue filter, respectively;

FIG. 3D shows a schematic curve of transmission versus wavelength of a lens with dual band filtering adaptable to the CFA of FIG. 3A; and

FIG. 4 schematically shows a method of reading out signals from the image sensor of FIG. 3A.

### DETAILED DESCRIPTION OF THE INVENTION

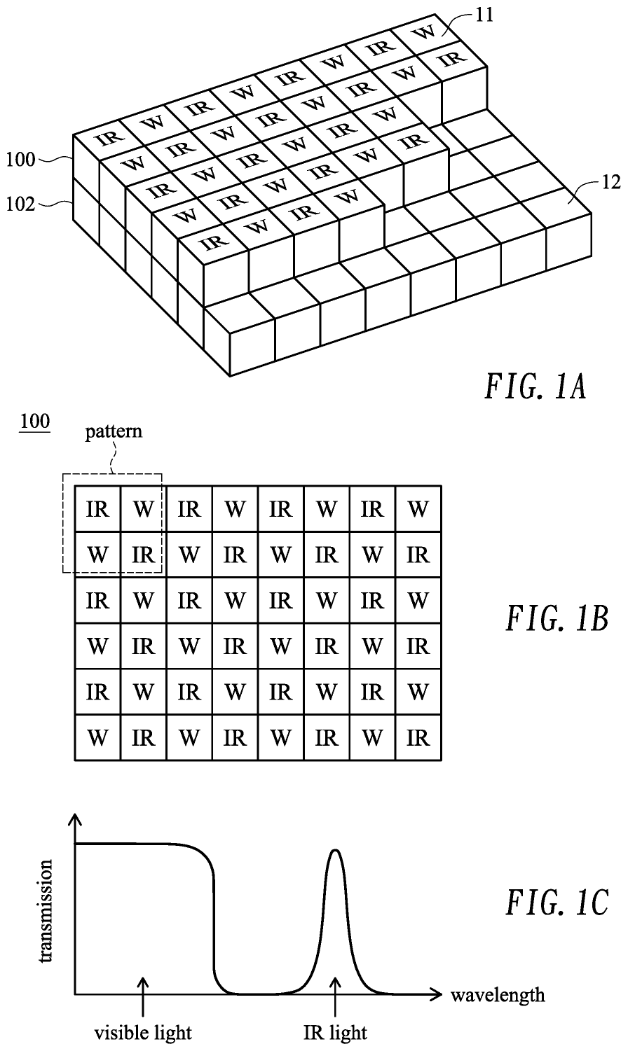

FIG. 1A shows a perspective view of a color filter array (CFA) 100 disposed on an image sensor 102 according to a first embodiment of the present invention. Specifically, the image sensor 102, for example, a complementary metal-oxide-semiconductor (CMOS) image sensor or CIS, may include a plurality of pixel sensors (or photo sensors) 12. The CFA 100 of the embodiment may include a plurality of pixel filters (or filters for short) 11 that are correspondingly aligned with the pixel sensors 12. For better viewing, only partial pixel filters 11 are depicted.

FIG. 1B shows a top view of the CFA 100 of FIG. 1A. Specifically, the pixel filters 11 of the CFA 100 are arranged in a predetermined (repetitive) pattern composed of 2×2 pixel filters 11 including two infrared (IR) filters and two visible (light) filters. In the embodiment, the two visible filters are white (or transparent) filters (W). Particularly, the two IR filters are disposed along one diagonal and the two white filters are disposed along another diagonal. FIG. 1C shows a schematic curve of transmission versus wavelength of a lens (not shown) with dual band filtering adaptable to the CFA 100 of FIG. 1A. It is noted that the IR light band in FIG. 1C may be 800-860 nm, and the transmission peak may be 840 nm. Actually, the curve of FIG. 1C depends on the material or coating.

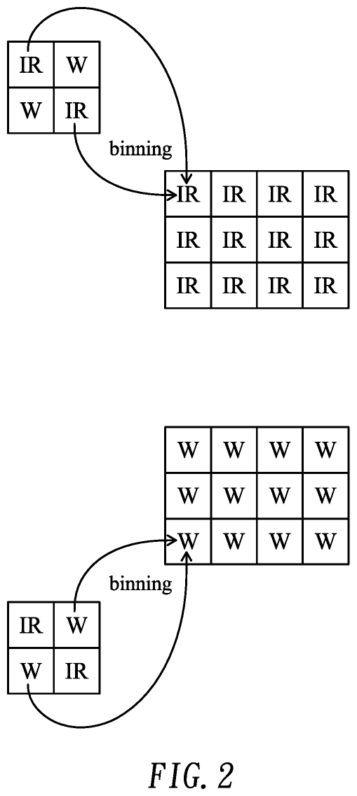

FIG. 2 schematically shows a method of reading out signals from the image sensor 102 of FIG. 1A. In the embodiment, IR signals from the pixel sensors 12 corresponding to the IR filters and visible signals (specifically white signals in this embodiment) from the pixel sensors 12 corresponding to the white filters are read out separately.

Specifically, the IR signals from the pixel sensors 12 corresponding to the two IR filters within the predetermined pattern are combined (i.e., binning) to result in a combined IR signal within the pattern, thereby getting better sensitivity. The combined IR signals of the entire image sensor 102 constitute an IR image, which is one quarter the resolution of the image sensor 102. For example, the image sensor 102 has resolution of 960×800, and the associated IR image thus has resolution of 480×400.

Simultaneously, the white signals from the pixel sensors 12 corresponding to the two white filters within the predetermined pattern are combined (i.e., binning) to result in a combined white signal within the pattern, thereby getting better sensitivity. The combined white signals of the entire image sensor 102 constitute a visible image (specifically a monochrome image in this embodiment), which is one quarter the resolution of the image sensor 102. For example, the image sensor 102 has resolution of 960×800, and the associated monochrome image thus has resolution of 480×400.

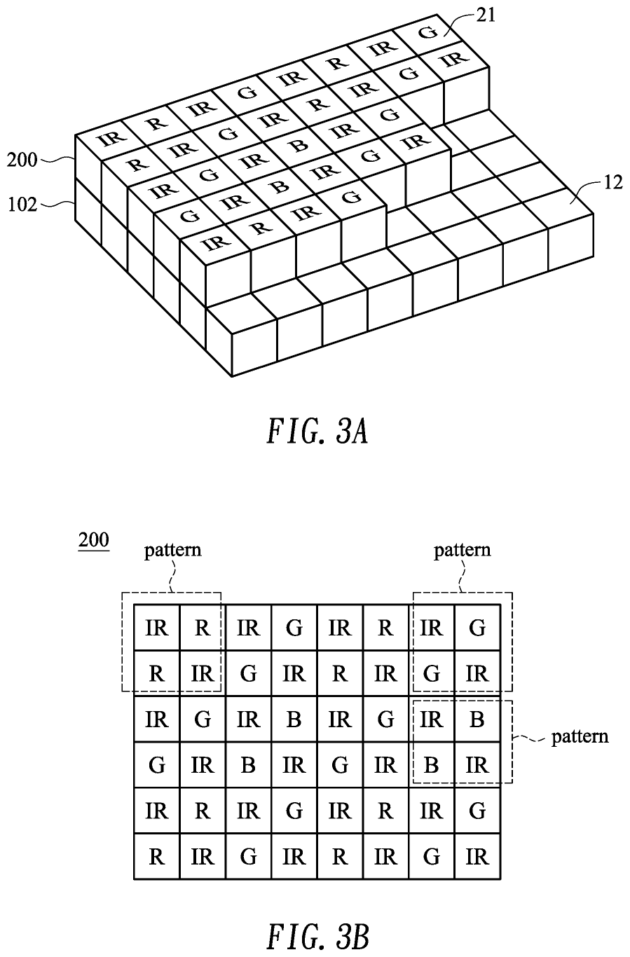

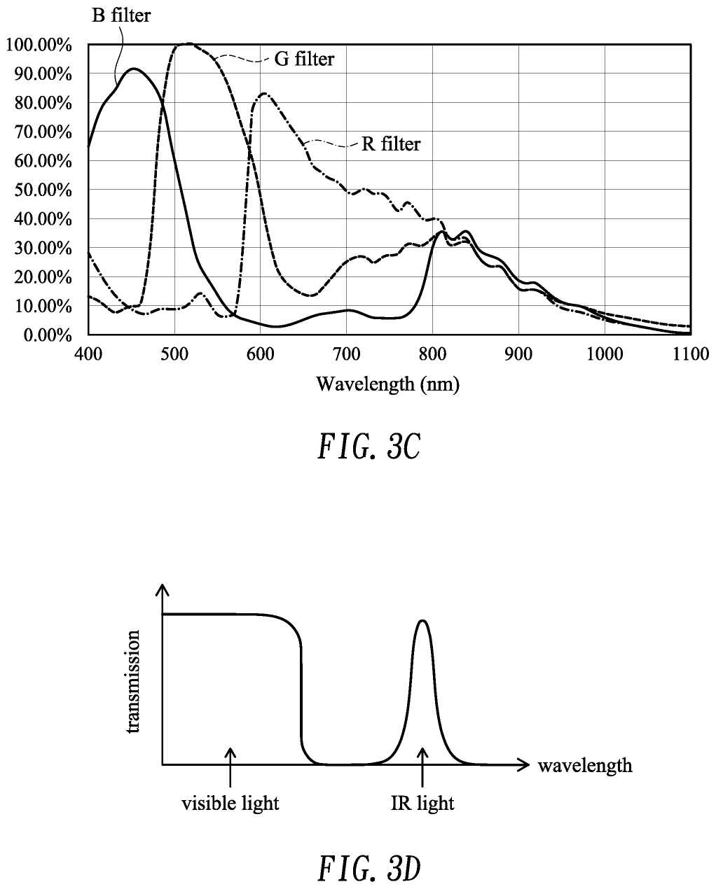

FIG. 3A shows a perspective view of a color filter array (CFA) 200 disposed on an image sensor 102 according to a second embodiment of the present invention. Specifically, the image sensor 102, for example, a CMOS image sensor or CIS, may include a plurality of pixel sensors (or photo sensors) 12. The CFA 200 of the embodiment may include a plurality of pixel filters (or filters for short) 21 that are correspondingly aligned with the pixel sensors 12.

FIG. 3B shows a top view of the CFA 200 of FIG. 3A.

Specifically, the pixel filters 21 of the CFA 200 are arranged in a predetermined pattern composed of 2×2 pixel filters 21 including two infrared (IR) filters and two visible (light) filters. In the embodiment, the two visible filters are (same) color filters that are either red (R) filters, green (G) filters or blue (B) filters. Particularly, the two IR filters are disposed along one diagonal and the two color filters are disposed along another diagonal. It is noted that, in the embodiment, the color filters of the entire CFA 200 are half green, one quarter red and one quarter blue, and are arranged with Bayer arrangement. FIG. 3C shows schematic curves of transmission versus wavelength of a red filter, a green filter and a blue filter, respectively. It is noted that, in addition to a specific band through which light of specific color can pass, the filter may also pass a small amount of other light (e.g., infrared). FIG. 3D shows a schematic curve of transmission versus wavelength of a lens (not shown) with dual band filtering adaptable to the CFA 200 of FIG. 3A.

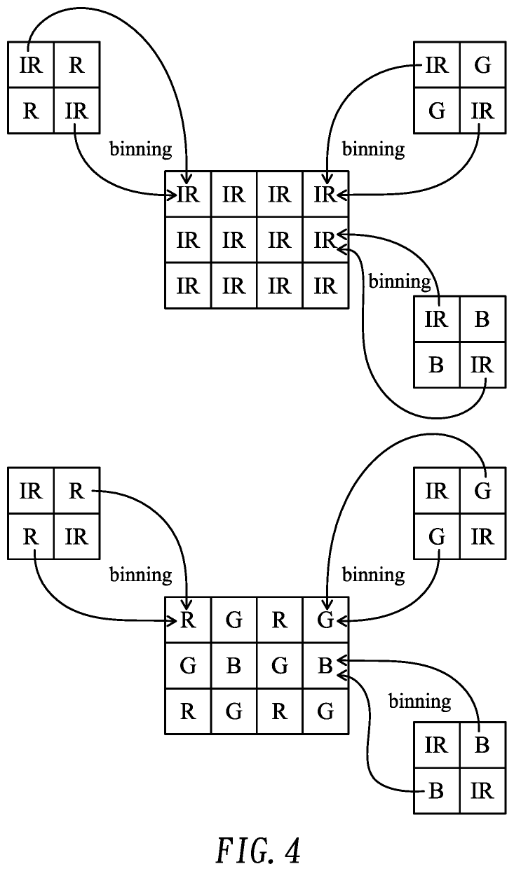

FIG. 4 schematically shows a method of reading out signals from the image sensor 102 of FIG. 3A. In the embodiment, IR signals from the pixel sensors 12 corresponding to the IR filters and visible signals (specifically color signals in this embodiment) from the pixel sensors 12 corresponding to the color filters (i.e., R, G and B) are read out separately.

Specifically, the IR signals from the pixel sensors 12 corresponding to the two IR filters within the predetermined pattern are combined (i.e., binning) to result in a combined IR signal within the pattern. The combined IR signals of the entire image sensor 102 constitute an IR image, which is one quarter the resolution of the image sensor 102. For example, the image sensor 102 has resolution of 960×800, and the associated IR image thus has resolution of 480×400.

Simultaneously, the color signals from the pixel sensors 12 corresponding to the two color filters within the predetermined pattern are combined (i.e., binning) to result in a combined color signal within the pattern. The combined color signals of the entire image sensor 102 constitute a visible image (specifically a color (or RGB) image in this embodiment), which is one quarter the resolution of the image sensor 102. For example, the image sensor 102 has resolution of 960×800, and the associated color image thus has resolution of 480×400.

According to the CFA 100 or the CFA 200 with the predetermined pattern and the associated read out method as described above, higher sensitivity and signal-to-noise ratio (for the IR image) and less artifact (for the monochrome or color image) can be achieved after being processed by an image signal processor (ISP) as compared with conventional CFAs.

It is noted that the infrared image and the monochrome image in the first embodiment may be simultaneously and separately obtained for different applications, thereby realizing a dual mode image sensor. Similarly, the infrared image and the color image in the second embodiment may be simultaneously and separately obtained for different applications, thereby realizing a dual mode image sensor.

The CFA 100 or the CFA 200 in companion with the image sensor 102 may constitute an artificial intelligence smart sensor adaptable to artificial intelligence (AI) applications. Specifically, the IR image obtained in the embodiment, in companion with an IR light source for enhancing image quality, may be used for biometric recognition (e.g., facial recognition) capable of identifying individuals by human characteristics. For example, the IR image obtained in the embodiment may be used in Windows Hello, a biometrics-based technology that authenticates secure access with a fingerprint, iris scan or facial recognition. On the other hand, the monochrome image or the color image obtained in the embodiment may be used for surveillance capable of monitoring behavior or activities for the purpose of information gathering. For example, the monochrome image or the color image obtained in the embodiment may be used to detect an approaching or leaving person, based on which an electronic device (e.g., computer) may accordingly wake up or sleep. Therefore, the dual-mode image sensor disclosed in the embodiments can simultaneously and separately provide the infrared image and the monochrome/color image, thereby providing cost effective solution and allowing flexibility on video camera.

Although specific embodiments have been illustrated and described, it will be appreciated by those skilled in the art that various modifications may be made without departing from the scope of the present invention, which is intended to be limited solely by the appended claims.

What is claimed is:

1. A color filter array, comprising:
a plurality of pixel filters arranged in a predetermined pattern composed of 2×2 pixel filters including two infrared filters and two visible filters;
wherein the two infrared filters in the predetermined pattern are disposed along one diagonal, and the two visible filters in the predetermined pattern are disposed along another diagonal.

2. The color filter array of claim 1, wherein the two visible filters in the predetermined pattern comprise two white filters or transparent filters.

3. The color filter array of claim 1, wherein the two visible filters in the predetermined pattern comprise two same color filters that are either red filters, green filters or blue filters.

4. The color filter array of claim 3, wherein color filters of the entire color filter array are half green, one quarter red and one quarter blue, and are arranged with Bayer arrangement.

5. A dual-mode image sensor, comprising:
a plurality of pixel sensors; and
a plurality of pixel filters that are correspondingly aligned with the plurality of pixel sensors, the plurality of pixel filters being arranged in a predetermined pattern composed of 2×2 pixel filters including two infrared filters and two visible filters, the two infrared filters in the predetermined pattern being disposed along one diagonal and the two visible filters in the predetermined pattern being disposed along another diagonal;
wherein infrared signals from pixel sensors corresponding to the infrared filters and visible signals from pixel sensors corresponding to the white filters are read out separately.

6. The dual-mode image sensor of claim 5, wherein the infrared signals from the pixel sensors corresponding to the two infrared filters within the predetermined pattern are combined to result in a combined infrared signal within the pattern, and combined infrared signals of all the plurality of pixel sensors constitute an infrared image.

7. The dual-mode image sensor of claim 6, wherein the visible signals from the pixel sensors corresponding to the two visible filters within the predetermined pattern are combined to result in a combined visible signal within the pattern, and combined visible signals of all the plurality of pixel sensors constitute a visible image.

8. The dual-mode image sensor of claim 7, wherein the infrared image is used for biometric recognition capable of identifying individuals by human characteristics, and the visible image is used for surveillance capable of monitoring behavior or activities for purpose of information gathering.

9. The dual-mode image sensor of claim 5, wherein the two visible filters in the predetermined pattern comprise two white filters or transparent filters.

10. The dual-mode image sensor of claim 5, wherein the two visible filters in the predetermined pattern comprise two same color filters that are either red filters, green filters or blue filters.

11. The dual-mode image sensor of claim 10, wherein color filters of all the plurality of pixel filters are half green, one quarter red and one quarter blue, and are arranged with Bayer arrangement.
